(19) United States
(12) Patent Application Publication
(10) Pub. No.: US 2006/0164167 A1
(43) Pub. Date: Jul. 27, 2006

(54) Linear commutating amplifier

(75) Inventor: Ronald M. Hickling, Newburry Park, CA (US)

Correspondence Address: INTELLECTUAL PROPERTY LAW OFFICE OF JOEL VOELZKE, 400 CORPORATE POINTE, SUITE 300, CULVER CITY, CA, 90230, US

(73) Assignee: TechnoConcepts, Inc.

(21) Appl. No.: 11/219,238

(22) Filed: Sep. 2, 2005

Related U.S. Application Data
(60) Provisional application No. 60/646,082, filed on Jan. 21, 2005.

(51) Int. Cl. H03F 3/68

(52) U.S. Cl. 330/295

(57) ABSTRACT

An amplifier compensates for inherent non-linearities in its open loop behavior by using a first amplification stage configured as a voltage follower to follow an input voltage, which produces a signal that corresponds to the inverse of the non-linear transfer characteristic of the open loop amplifier used within that first stage, and using that inverse signal as the minus input to a second amplifier stage which is matched to the first amplifier stage. The result is that the output of the second amplifier stage has a highly linear response to the input voltage. The linear commutating amplifier may be applied to perform the commutation function within a direct conversion delta-sigma transmitter or a direct conversion delta-sigma receiver.

### CROSS-REFERENCE TO RELATED APPLICATIONS

This application claims the benefit of U.S. provisional patent application Ser. No. 60/646,082 filed Jan. 21, 2005.

### BACKGROUND OF THE INVENTION

1. Field of the Invention

This invention relates to the field of electronic circuits. More particularly, this invention relates to a linear commutating amplifier.

2. Background of the Invention

The front end stage of most radio frequency (RF) receivers, whether they be of the superheterodyne or direct conversion type, includes a mixer that is used to translate the frequency spectrum of the incoming waveform from having a given center frequency (the carrier frequency) to a having a different (and usually lower) center frequency.

FIG. 1 shows a typical mixer representation in a RF receiver. An incoming RF signal is received by antenna 10, typically amplified by amplifier 12, and then downconverted in mixer 16. The mixer building block is designed to approximate the mathematical operation of multiplying the incoming RF signal applied at the radio frequency port (commonly designated “R”) with a sine wave produced by a local oscillator 14 applied at the local oscillator port (commonly designated “L”). The resulting output is presented at the intermediate frequency output port (commonly designated “X”). The resulting output includes versions of the received signal shifted to both the carrier frequency plus the local oscillator frequency, and to the carrier frequency minus the local oscillator frequency. That is, in the typical case the resulting output contains both a high frequency version of the incoming signal and an intermediate frequency version of the incoming signal.

Mixer 16 can be implemented using a number of circuit approaches ranging from a simple “diode ring” mixer to a configuration that is referred to as a Gilbert multiplier cell. The ability of these analog circuits to faithfully implement the mathematical model of signal multiplication has been a fundamental limiting factor in the creation of receiver designs having a high dynamic range. The extent to which the hardware implementation of a mixer deviates from the ideal mathematical model of signal multiplication determines the extent to which the mixer produces intermodulation distortion (IMD), or signals at frequencies other than that predicted by the operation of multiplication.

Ideally, if a sinusoidal signal with frequency f₀ is applied at the “R” input and a sinusoidal signal with frequency f₁ is applied to the “L” input, the signal produced at the “X” output would only contain components at the frequencies |f₀+f₁| and |f₀−f₁|. However, hardware implementations of mixers have a tendency to additionally produce “spurious” outputs at a multitude of other frequencies |m·f₀±n·f₁|, where m and n are integers, and the value m+n is designated to be the “order” of the spurious product.

An alternative mathematical process to multiplying an incoming signal by a pure sine wave is multiplying it by the alternating sequence +1, −1, +1, −1, . . . . In discrete time, this process produces the result:

$$y ( n ) = {( - 1 )}^{n} \cdot x ( n )$$

$$Y ( {ⅇ}^{jω} ) = X ( {ⅇ}^{jω} ) ⊗ F \{ {( - 1 )}^{n} \}$$

$$Y ( {ⅇ}^{jω} ) = X ( {ⅇ}^{jω} ) ⊗ \frac{1}{2} [ {\sum }_{k = 0}^{∞} ( 1 - {ⅇ}^{- jπ \cdot k} ) \cdot δ ( ω - π \cdot k ) ]$$

$$Y ( {ⅇ}^{jω} ) = {\sum }_{k odd} X ( {ⅇ}^{j ( ω - π \cdot k )} )$$

The above result suggests that an input spectrum centered around ω=π+Δ where π is the radial frequency of the incoming digital samples and Δ is an arbitrary small separation from the center frequency, will produce an output spectrum with images centered around ω=Δ, 2π+Δ, 4π+Δ, etc., when f_{carrier}=f_{clock}/2 Thus, a baseband image (centered around zero frequency) results, with the nearest repetition of that image being centered around the clock frequency. This is effectively a translation of the spectrum by an amount ω=π. Aliasing is avoided so long as the bandwidth of the spectrum is limited to Δω<π/2.

FIG. 2 shows the spectral analysis of the commutation operation in discrete time. The spectrum of the incoming signal (centered around ω=π, and having an image around ω=−π) is shown via unfilled curves 22 and 21. Multiplying this signal by the sequence (−1)ⁿ results in a spectrum centered around ω=0, i.e., baseband, with additional harmonics centered around ω=2π and ω=−2π. That output spectrum is shown via the filled curves 20, 23 and 24. As long as the incoming spectrum is sufficiently bandlimited, the higher order harmonics are sufficiently separated from baseband and aliasing is avoided.

For continuous time systems, the incoming signal is multiplied by a square wave alternating in value between +1 and −1 during opposite half-cycles. The continuous time multiplication produces the result:

$$y ( t ) = x ( t ) \cdot sq ( t )$$

$$sq ( t ) ≡ \{ \begin{matrix}1 & ∀ t ∋ n \cdot T \leq t \leq n \cdot T + \frac{T}{2} \\ - 1 & ∀ t ∋ n \cdot T + \frac{T}{2} \leq t \leq ( n + 1 ) \cdot T\end{matrix} \}$$

$$Y ( jω ) = X ( jω ) ⊗ F ( sq ( t ) )$$

$$Y ( jω ) = X ( jω ) ⊗ {\sum }_{k odd} \frac{2}{j \cdot k π} \cdot [ δ ( ω - \frac{2 π k}{T} ) - δ ( ω + \frac{2 π k}{T} ) ]$$

$$Y ( jω ) = {\sum }_{k odd} \frac{2}{j \cdot k π} \cdot [ X ( j ( ω - \frac{2 π k}{T} ) ) - X ( j ( ω + \frac{2 π k}{T} ) ) ]$$

The above result indicates that if an incoming signal with a spectrum that is centered about the frequency Ω=2π/T (which corresponds to the normalized radial frequency ω=2π) is commutated by a square wave with a period T, where π is the radial frequency of the incoming signal, the output signal will contain one image of the signal at “baseband,” one image of the signal centered about Ω=4π/T, and additional images of the signal centered about Ω=2π/T±2πk/T for k=odd integers (i.e., the even harmonics of Ω=2π/T).

FIG. 3 shows these results. FIG. 3 is the spectral analysis of the commutation operation in continuous time. The spectrum of the incoming signal (centered around n=2/T) is shown via unfilled curve 31. Multiplying the incoming sequence by a square wave with period T=1 alternating between +1 and −1 results in the spectrum shown by solid fill curves 30, 32, 34, 36, etc. The spectral power within each of the two most adjacent images (centered around ω=0 and ω=4π, respectively) is scaled down from the spectral power of the input signal by a factor of 2/π.

Note that for practical purposes commutation and mixing produce virtually identical results at frequencies of interest. It is, however, significantly easier to implement a commutator, which only requires switching, than to develop an analog circuit that faithfully implements mathematical multiplication of two signals. This has already been discussed in U.S. Pat. No. 6,748,025, which is hereby incorporated by reference.

### SUMMARY OF THE INVENTION

The present invention exploits the ability of a signal follower stage such as a voltage follower to produce, in response to an input signal, a signal whose transfer characteristic relative to the input signal is approximately the inverse of the nonlinearity of the amplifier used within the input follower. That signal is then used as the minus or inverting input to a second amplification stage which is matched to the first amplifier, and with the input signal being used as the plus or non-inverting input to the second amplification stage. The result is that the output of the second amplifier is highly linear in response to the input signal to the circuit.

In one aspect, the invention is of a circuit comprising: a first stage comprising an input follower having plus and minus differential inputs with the output connected to the minus input to form a feedback loop; a second stage comprising an amplification stage having plus and minus differential inputs; wherein the input signal is connected to the non-inverting inputs to both the input follower stage and the amplification stage, and the output of the input follower is connected to the inverting input to the amplification stage. In an illustrative embodiment the input follower comprises a voltage-to-current converter in combination with a resistor which acts as a current-to-voltage converter, and the amplification stage comprises a second voltage-to-current converter. The voltage-to-current converters represent a variation of the Gilbert cell multiplier circuit. The second voltage-to-current converter is formed on the same semiconductor circuit die and is matched as closely as possible in architecture and layout to the first voltage-to-current converter in order to ensure that the non-linear characteristics of the first and second voltage-to-current converters are as close to identical as possible. The output of the input follower, which also defines the feedback signal within the input follower, thus has nonlinearities that are ideally the exact inverse of the non-linearities associated with the voltage-to-current converter that defines the amplification stage. By using that feedback signal as the inverting input to the second stage, the difference between the plus input and the minus input to the amplification stage corresponds to a high degree to the inverse of the non-linear characteristic of the amplification stage, thus greatly linearizing the overall transfer function of the device.

In another aspect, the invention is of a commutating circuit for commutating an input signal comprising: a first voltage-to-current converter which receives an input signal; a second voltage-to-current converter with one node of a differential input thereto connected to the input signal; a current-to-voltage converter for converting an output from the first voltage-to-current converter to a negative input to the first voltage-to-current converter thus defining a feedback loop, the feedback signal also connected to a second node of the differential input to the second voltage-to-current converter; and a current mode switch connected to an output of the second voltage-to-current converter; wherein the first voltage-to-current converter and the current-to-voltage converter together form a closed loop amplifier having an open loop gain of significantly greater than one and a closed loop gain of approximately unit. The open loop gain is preferably greater than 20, and more preferably greater than 1000.

In yet another aspect, the invention is of a method of linearizing an amplifier, comprising: providing two closely matched amplification sections on a single semiconductor substrate, amplifying within the second amplification section a difference between the input signal and an output from the first amplification section in response to the input; wherein the difference has nonlinear behavior produced by characteristics of the first amplification section that approximates the inverse of nonlinear behavior of the second amplification section, thereby at least partially compensating for the nonlinear behavior within the second amplification section and producing a more nearly linear overall transfer function than for the second amplification section alone.

The device can be used for example as a commutating amplifier either within a receiver to downconvert a signal from RF directly to baseband without first converting the signal to an intermediate frequency, or within a transmitter to upconvert a signal from baseband to RF for transmission over a wireless communication network without first converting the signal to an intermediate frequency.

Exemplary embodiments of the invention will be further described below with reference to the drawings, in which like numbers refer to like parts.

### BRIEF DESCRIPTION OF THE DRAWINGS

FIG. 1 is a block diagram showing a mixer within a conventional RF receiving circuit.

FIG. 2 is a spectral plot illustrating the spectrum produced by discrete time commutation.

FIG. 3 is a spectral plot illustrating the spectrum produced by continuous time commutation.

FIG. 4 is an equivalent block diagram of a commutating amplifier.

FIG. 5A is a block diagram showing a commutating amplifier implemented using a current-steering approach.

FIG. 5B is a schematic diagram illustrating the current steering commutating amplifier of FIG. 5A implemented using bipolar junction transistors.

FIG. 5C is a schematic diagram illustrating the current steering commutating amplifier of FIG. 5A implemented using field effect transistors.

FIG. 6 a block diagram of an amplifier configured as a current follower.

FIG. 7 is a plot showing the closed loop gain of the circuit of FIG. 6 as a function of the open loop gain of amplifier 66.

FIG. 8A is a time domain plot of the open loop gain and the closed loop gain of the amplifier of FIG. 6.

FIG. 8B is frequency domain plot of the open loop and closed loop gains of the amplifier of FIG. 6.

FIG. 9A is a plot of the output of the voltage follower of FIG. 6 as a function of the input.

FIG. 9B is plot of the difference signal ε=Vᵢₙ−Vₒᵤₜ of the voltage follower of FIG. 6 as a function of the input.

FIG. 10A is a block diagram of a linear commutating amplifier according to a first and common mode embodiment of the present invention.

FIG. 10B is a schematic diagram of an implementation of the linear commutating amplifier of FIG. 10A using bipolar junction transistors.

FIG. 10C is a schematic diagram of an implementation of the linear commutating amplifier of FIG. 10A using field effect transistors.

FIG. 11A is a block diagram of a linear commutating amplifier according to a second and differential mode embodiment of the present invention.

FIG. 11B is a schematic diagram of an implementation of the linear commutating amplifier of FIG. 11A using bipolar junction transistors.

FIG. 11C is a schematic diagram of an implementation of the linear commutating amplifier of FIG. 11A using field effect transistors.

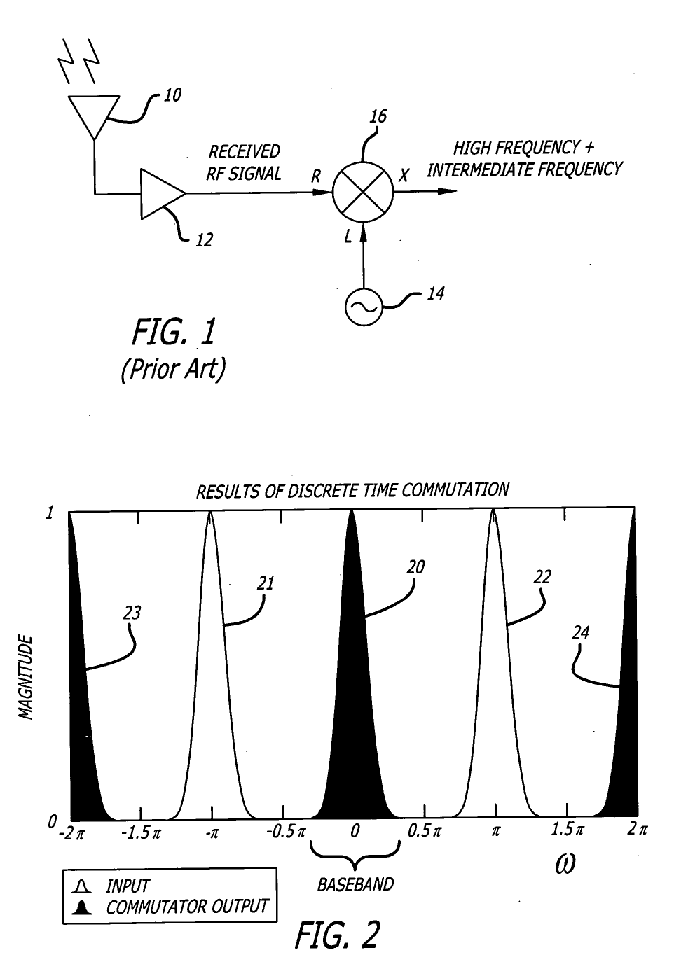

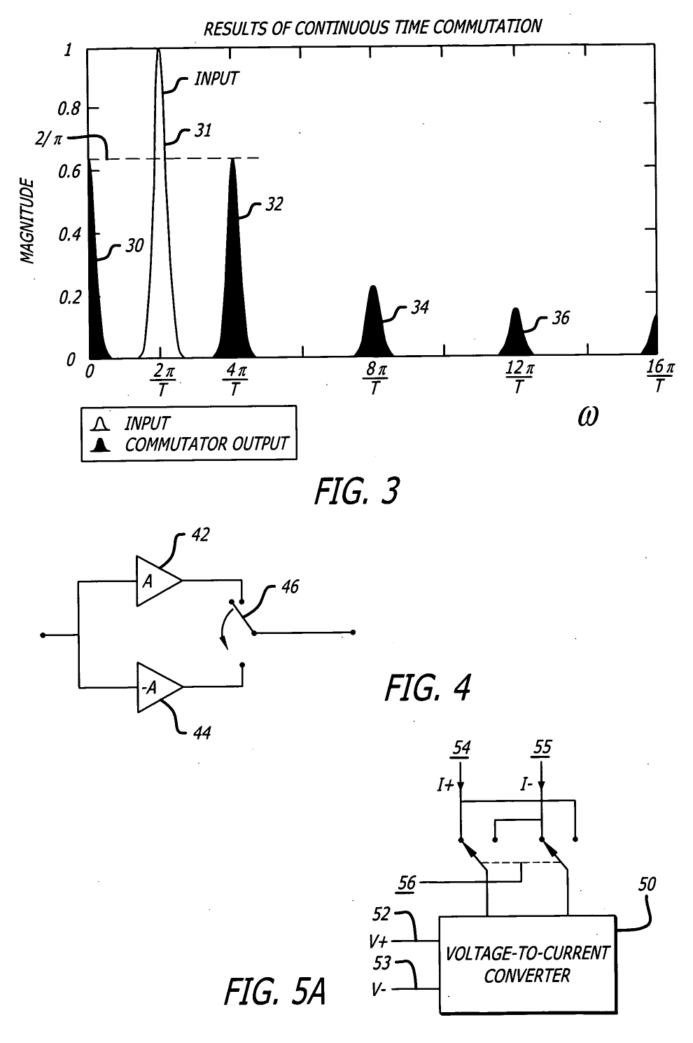

### DETAILED DESCRIPTION OF THE PREFERRED EMBODIMENTS

### Conceptual Discussion

FIG. 4 is a functional block diagram of a commutating amplifier. On every half-cycle of the clock, switch 46 toggles its position, causing first non-inverting amplifier 42 having gain A to be connected to the output, followed by inverting amplifier 44 having gain −A to be connected to the output. The result is that the output follows the pattern Ax, −Ax, Ax, −Ax, . . .

This mathematical operation can be implemented using several methods. In relatively low speed applications, the simplest implementation is accomplished through the use of MOS switches. Such an implementation is well within the capabilities of modern switched-capacitor technologies, and is compatible with switched-capacitor delta-sigma analog-to-digital converter circuits.

However, switched-capacitor technologies have severe speed limitations that make them undesirable for circuits with high clock speeds, such as in excess of 500 MHz. Circuits operating at such high speeds must be implemented using silicon or SiGe bipolar emitter-coupled approaches, or GaAs MESFET source-coupled approaches. These modern high-speed technologies, however, are severely disadvantaged in that low leakage switches are not very easily implemented. Thus an alternate method for gain inversion must be developed.

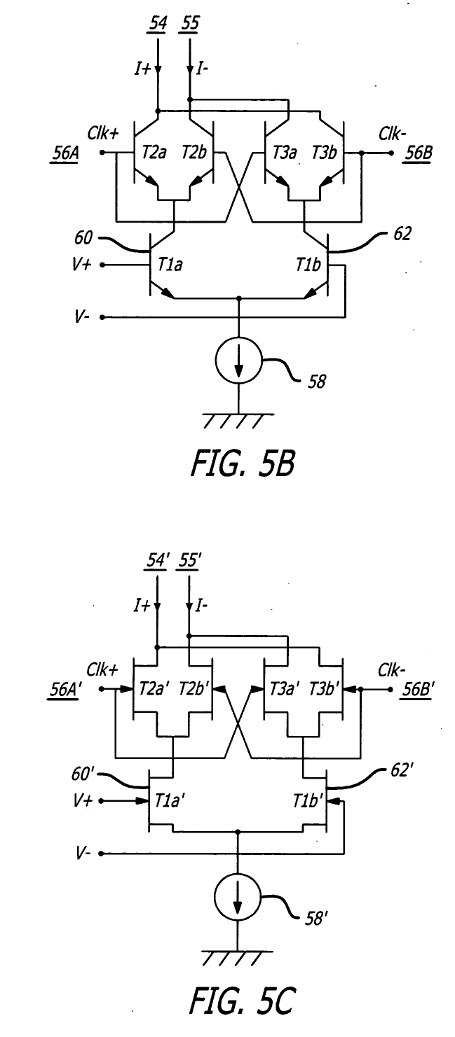

FIG. 5A illustrates the basic design paradigm of a commutating amplifier using the current-steering approach. A common mode input voltage 52 or a differential mode input voltage 52/53 is applied to the input of voltage-to-current converter 50. The voltage-to-current converter 50 sinks current 54 and 55 flowing into the current legs. The change in currents 54 and 55 is highly responsive to changes in the input voltage. Switch input 56 causes the currents into the voltage-to-current converter to be reversed.

The current steering approach is commonly used in high speed bipolar and MESFET designs because of its inherent speed. In this approach, a differential input voltage is converted into a differential current by means of a current steering network. The current steering network usually takes the form of a stacked network of emitter-coupled or source-coupled transistor pairs, such as shown in FIGS. 5B and 5C.

FIG. 5B is a schematic diagram illustrating the current steering commutating amplifier of FIG. 5A implemented using bipolar junction transistors (BJTs). Emitter-coupled transistors 60 and 62 at the base of the current steering network operate in their active regions, thus translating a small change in the input voltage into a large change in the differential current 54/55, according to the β value of the transistors T1a and T1b. Clock inputs 56A and 56B control whether currents I+ and I− are respectively steered through transistor 60 or transistor 62.

FIG. 5C is a schematic diagram illustrating the current steering commutating amplifier of FIG. 5A implemented using field effect transistors. Source-coupled transistors 60′ and 62′ at the base of the current steering network operate in their linear regions, thus translating a small change in the input voltage into a large change in the differential current 54/55. Clock inputs 56A′ and 56B′ control whether currents I+ and I− are respectively steered through transistor 60′ or transistor 62′. The structures shown in FIGS. 5B and 5C represent modifications to the basic Gilbert multiplier structure.

As can be inferred from an analysis of FIGS. 5A and 5B or 5C, the linearity of a commutating amplifier that is based upon a current steering approach is primarily limited by the linearity of the voltage-to-current converter that is at the base of the current switching network. Provided that the terminals Clk+ and Clk− are driven with a sufficiently large differential signal as to ensure that current passes exclusively through transistors T2a and T3a or transistors T2b and T3b, the linearity of the commutating amplifier is limited strictly by the voltage-to-current transfer characteristic of the transistor pair T1a/T1b. Most differential pairs are, in fact, fairly nonlinear with respect to their voltage-to-current transfer characteristic, particularly when driven by large input signals. The transfer function is relatively linear for differential input voltages (Vin+−Vin−) very close to zero volts. For large differential input voltages, the transfer characteristic becomes extremely nonlinear.

The function of the differential pairs T2a/T2b and T3a/T3b is to merely invert the sense of the current by swapping the positive and negative current output terminals (i.e., I+ and I−). Provided certain conditions are met, which will be discussed later, the value of the voltages applied to the Clk+ and Clk− input terminals merely determines the sense of the transfer characteristic between Vin+/Vin− and I+/I− and not the shape. Thus a linear commutating amplifier can be fashioned by applying predistortion to the inputs Vin+ and Vin− in such a way as to compensate for the distortion in the voltage-to-current transfer characteristic.

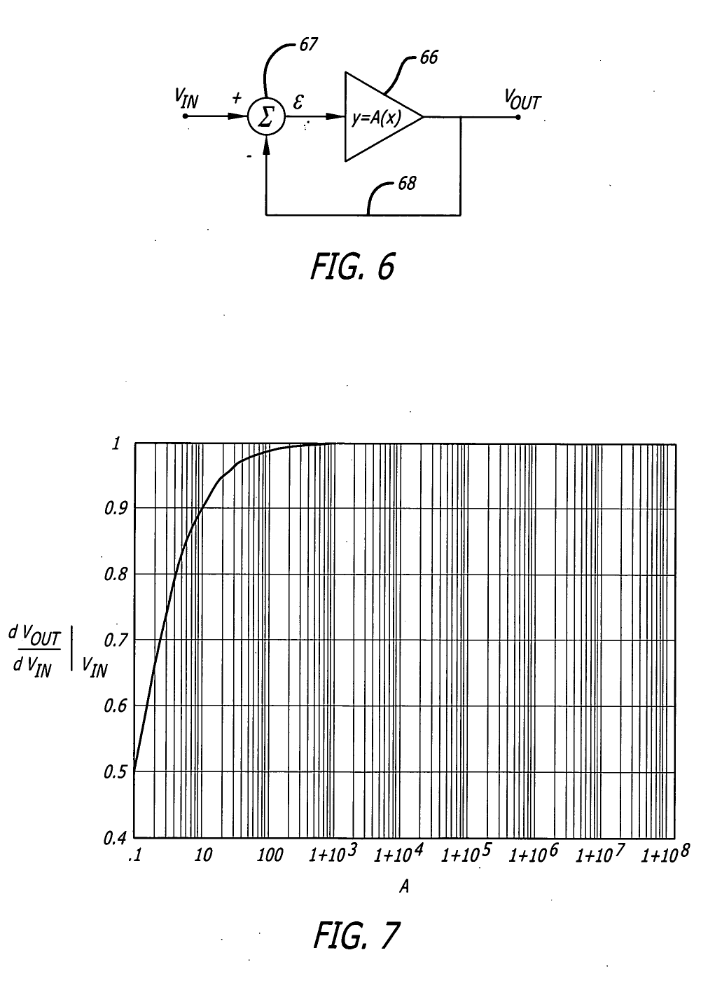

To understand how predistortion is accomplished, consider the block diagram of the feedback circuit in FIG. 6. The function A(x) is assumed to be that of a saturating amplifier. Such a function is characterized by three asymptotic behaviors:
(1) A(x)≈Aᵥ·x, (Aᵥ>>1), for x→0,
(2) A(x)≈y₀, (y₀>0), for x→∞, and
(3) A(x)≈−y₁, (y₁>0), for x→−∞.
   The nonlinear transfer function A(x) is a function that is very nearly linear in the neighborhood x=0 and has a first derivative that vanishes for large positive and negative values of x. In the figure, an open loop amplifier 66 has a transfer function y=A(x) which is not necessarily linear. The output of the amplifier is fed back to summer 67 which subtracts the output from the input to produce a differential signal ε, which becomes the input to open loop amplifier 66.

Analysis of the circuit yields the following equations:

$${V}_{out} = A ( ɛ ) = A ( {V}_{i n} - {V}_{out} )$$

$${A}^{- 1} ( {V}_{out} ) = {V}_{i n} - {V}_{out}$$

$${V}_{i n} = {V}_{out} + {A}^{- 1} ( {V}_{out} )$$

$$\frac{ⅆ {V}_{i n}}{ⅆ {V}_{out}} = 1 + \frac{ⅆ}{ⅆ {V}_{out}} {A}^{- 1} ( {V}_{out} )$$

The function A⁻¹(y) is the inverse of the function A(x), and is characterized by the following asymptotic behaviors:
(1) A⁻¹(y)≈y/A Aᵥ for y→0,
(2) A⁻¹(y)→∞ for y→y₀, and
(3) for y→−y₁.
Now assuming (as in this case) that A(•) is invertible such that y=A(x) and x=A⁻¹(y) are both functions, then:

$$\frac{ⅆ {V}_{i n}}{ⅆ {V}_{out}} = {[ \frac{ⅆ {V}_{out}}{ⅆ {V}_{i n}} ]}^{- 1} .$$

This equation predicts that in the neighborhood of Vₒᵤₜ=0:

$$\frac{ⅆ {V}_{i n}}{ⅆ {V}_{out}} {\vert}_{{V}_{out} = 0} = 1 + \frac{ⅆ}{ⅆ {V}_{out}} {A}^{- 1} ( {V}_{out} ) {\vert}_{{V}_{out} = 0} \\ \frac{ⅆ {V}_{i n}}{ⅆ {V}_{out}} {\vert}_{{V}_{out} = 0} = 1 + \frac{1}{{A}_{v}} = \frac{{A}_{v} + 1}{{A}_{v}}$$

$$\frac{ⅆ {V}_{out}}{ⅆ {V}_{i n}} = {[ \frac{ⅆ {V}_{i n}}{ⅆ {V}_{out}} ]}^{- 1} = \frac{{A}_{v}}{{A}_{v} + 1}$$

The above result agrees with that predicted by a linear analysis using an ideal linear amplifier model. More generally the small-signal gain can be expressed as:

$$\frac{ⅆ {V}_{out}}{ⅆ {V}_{i n}} = \frac{{[ \frac{ⅆ}{ⅆ {V}_{out}} {A}^{- 1} ( {V}_{out} ) ]}^{- 1}}{1 + {[ \frac{ⅆ}{ⅆ {V}_{out}} {A}^{- 1} ( {V}_{out} ) ]}^{- 1}} ,$$

where the expression:

$$[ \frac{ⅆ}{ⅆ {V}_{out}} {A}^{- 1} ( {V}_{out} ) ]$$

is the reciprocal of the small-signal gain of the amplifier. Thus the above equation can be expressed as follows:

$${A}_{cl} {\text{\vert}}_{{V}_{i n}} = \frac{{A}_{v} {\text{\vert}}_{{V}_{i n}}}{1 + {A}_{v} {\text{\vert}}_{{V}_{ i n}}}$$

where:
A_{cl}|_{V}_{ᵢₙ} is the small-signal closed loop gain evaluated for a given value of Vᵢₙ, and
Aᵥ|_{V}_{ᵢₙ} is the small-signal open loop gain evaluated for that same value of Vᵢₙ.

Taking a numerical example, if Vᵢₙ=1 VDC, and A=1000, then ε≈0.000999 V and Vₒᵤₜ≈0.999 V.

It is well known that negative feedback tends to reduce the sensitivity of the closed loop gain with respect to the open loop gain of a system. FIG. 7 shows a plot of closed loop gain versus open loop gain for the equation shown above. Note that as open loop gains exceed 1000, the deviation of the closed loop gain from the ideal value of unity approaches zero and is virtually undetectable. This, in fact, is revealed by doing a sensitivity analysis of closed loop gain with respect to open loop gain:

$$\frac{ⅆ {A}_{cl}}{ⅆ {A}_{v}} = \frac{( 1 + {A}_{v} ) - {A}_{v}}{{( 1 + {A}_{v} )}^{2}} = \frac{1}{{( 1 + {A}_{v} )}^{2}}$$

$$\frac{ⅆ {A}_{cl}}{ⅆ {A}_{v}} \cdot \frac{1 + {A}_{v}}{{A}_{v}} = \frac{ⅆ {A}_{cl}}{ⅆ {A}_{v}} \cdot \frac{1}{{A}_{cl}} = \frac{1}{{A}_{v} \cdot ( 1 + {A}_{v} )} = \frac{{A}_{cl}}{{A}_{v}^{2}}$$

$$\frac{ⅆ {A}_{cl}}{{A}_{cl}} = \frac{{A}_{cl}}{{A}_{v}} \cdot \frac{d {A}_{v}}{{A}_{v}}$$

Simply restated, the relative change of the closed loop gain is equal to the relative change of the open loop gain times the ratio of the closed loop gain to the open loop gain. For example, if the closed loop gain is unity and the open loop gain is 1000, the closed loop gain changes 1/1000% for each 1% change in open loop gain. By desensitizing the closed loop gain with respect open loop gain, the circuit is effectively linearized, since the small signal gain varies less across the output range of the circuit.

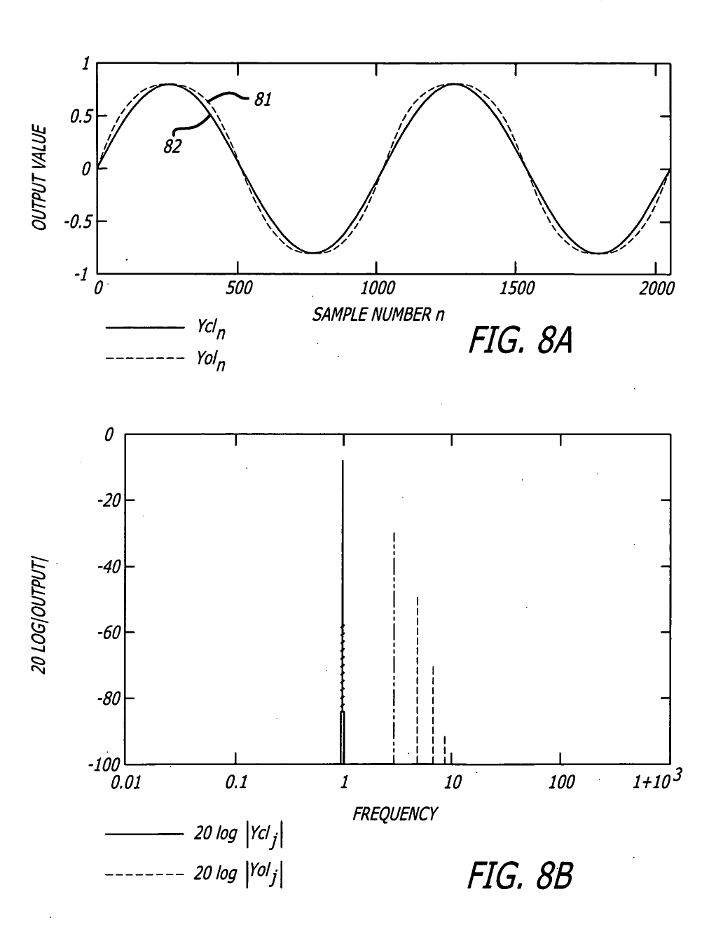

FIG. 8 shows a comparison of the distortion characteristics of a non-linear amplifier operated open loop with that of that same amplifier operated close loop according to a simulation. In these numerical simulations the open loop gain of the amplifier is 1000; the closed loop gain of the feedback amplifier is unity. Both are driven with a pure sine wave having an input amplitude having a sufficient amplitude to produce an output amplitude of 0.8V. FIG. 8A is the time domain response. The solid line 82 shows Vout, the closed loop gain, as a function of Vin in the time domain. The dotted line 81 represents what Vout would be if signal ε were a generally sinusoidal wave sufficient to cause Vout to have an amplitude of 0.8V.

FIG. 8B is the frequency domain analysis showing odd harmonics for the open loop response, where the frequency of the input sine wave is normalized to 1. A numerical distortion analysis shows the total harmonic distortion (THD) of the open loop response to be −22.2 dB and that of the closed loop response to be −99.6 dB. Thus, even though both amplifiers operate with the same output amplitude, the relative THD of the closed loop amplifier is dramatically less due to its more constant small signal gain.

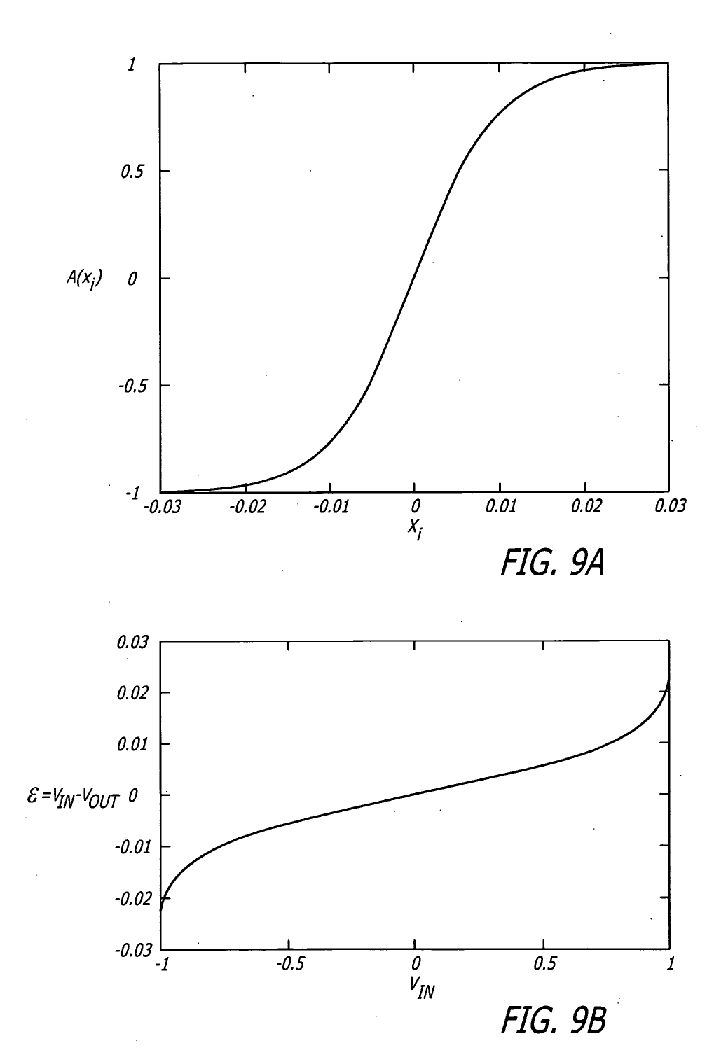

The key to this property of feedback amplifiers lies in the fact that the feedback has a tendency to predistort the input in such a way that the overall characteristic is very nearly linear. FIG. 9 compares the open loop transfer function A(x) shown in FIG. 6 to the transfer function of the amplifier input signal as a function of the input signal to the feedback amplifier. Specifically, FIG. 9A shows the amplification A(x) of the non-linear amplifier 66 as a function of the input x to that amplifier. FIG. 9B shows the input ε to the non-linear amplifier 66 as a function of Vᵢₙ.

The shape of this transfer curve FIG. 9B appears as the inverse of that in FIG. 9A. This is expected, since the product of these two curves must produce a nearly straight line with a slope of unity. Thus the feedback amplifier structure of FIG. 6 has effectively produced the inverse function of the open loop amplifier transfer characteristic A(x). This effect will be used in implementing the invention.

### Implementation

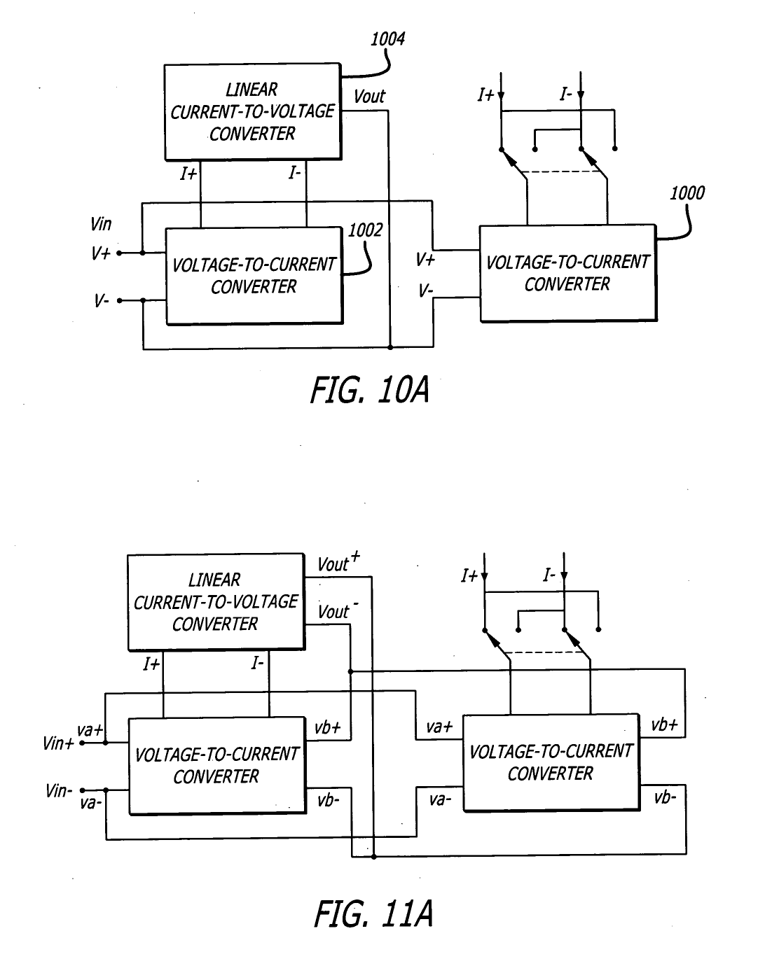

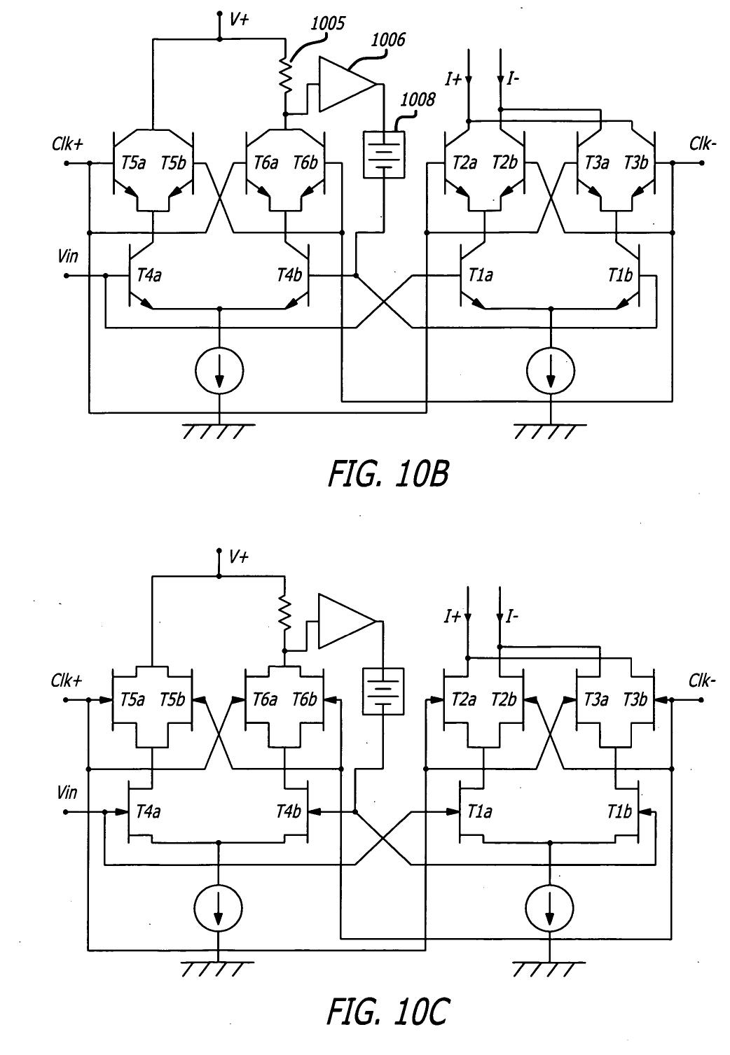

FIG. 10A is a basic block diagram of the linear commutating amplifier according to an illustrative embodiment of the invention. An input voltage V+ is provided as the non-inverting input to voltage-to-current converter 1002 and to voltage-to-current converter 1000, producing an amplified current output on current legs I+, I− of voltage-to-current converter 1002. A linear current-to-voltage converter 1004, which can be a implemented as simple resistors as shown by resistor 1005 in FIG. 10B, translates the current to a voltage Vout. This Vout is then fed back to the inverting input V− to the voltage-to-current converter. Voltage-to-current converter 1002 together with current-to-voltage converter 1004 are thus configured to define an input follower, and more specifically a voltage follower.

The Vout signal, which is both the feedback within the input follower stage as well as the output thereof, is also provided as the inverting input to voltage-to-current converter 1000 which defines an amplification stage. The output of the amplification stage then appears on the current legs I+ and I− of voltage-to-current converter 1000. This output can be converter to a voltage output if desired by adding a linear current-to-voltage converter such as a resistor, or a resistor pair for fully differential operation.

Conceptually, the invention implements a predistortion circuit by replicating (both from a circuit design and layout standpoint) the voltage-to-current converter circuitry of a non-linear commutating amplifier and creating a negative feedback amplifier that incorporates this voltage-to-current converter circuitry. Assuming that the gain of the amplifier formed by the combination of the voltage-to-current converter and the current-to-voltage converter is sufficiently high, the output Vout will tend to “follow” Vin, with the differential input to the voltage-to-current converter (i.e., V+−V−) being predistorted in such a way as to create a linear transfer characteristic between Vin and Vout. Thus, if these two voltages are simultaneously applied to the V+ and V− input terminals of the voltage-to-current converter associated with the non-linear commutating amplifier, the predistortion should identically linearize its voltage to current transfer characteristic. Preferably the gain of the amplifier used within the amplification stage is high, preferably being greater than 20, and more preferably being greater than 1000. The closed loop gain of the input follower stage will be approximately unity.

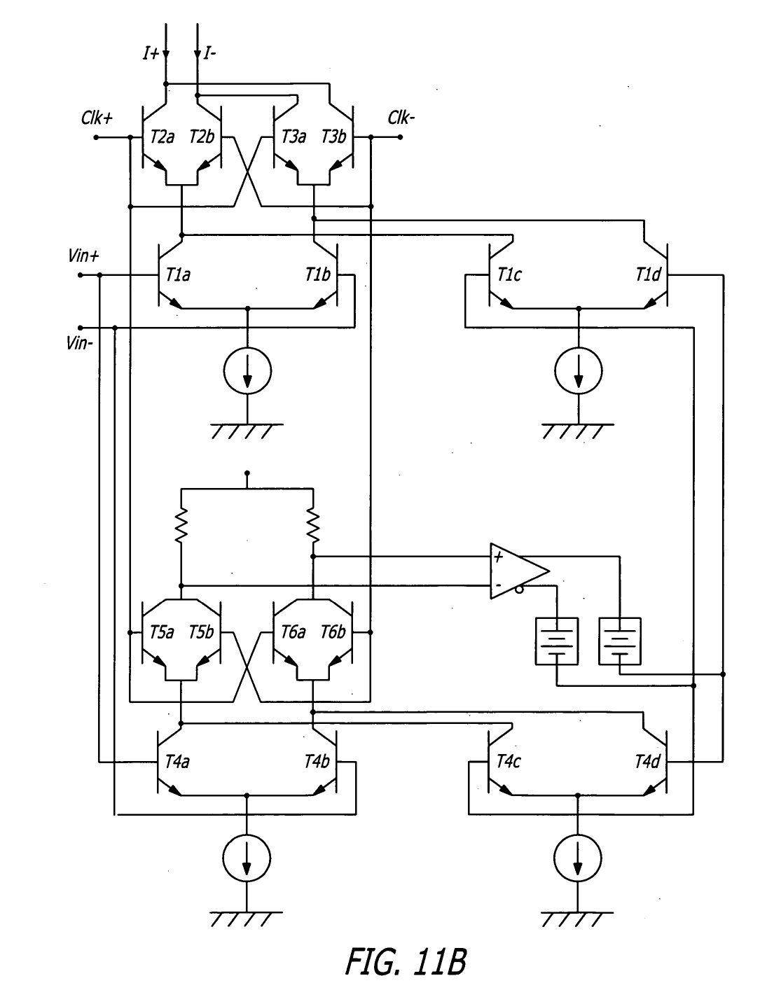

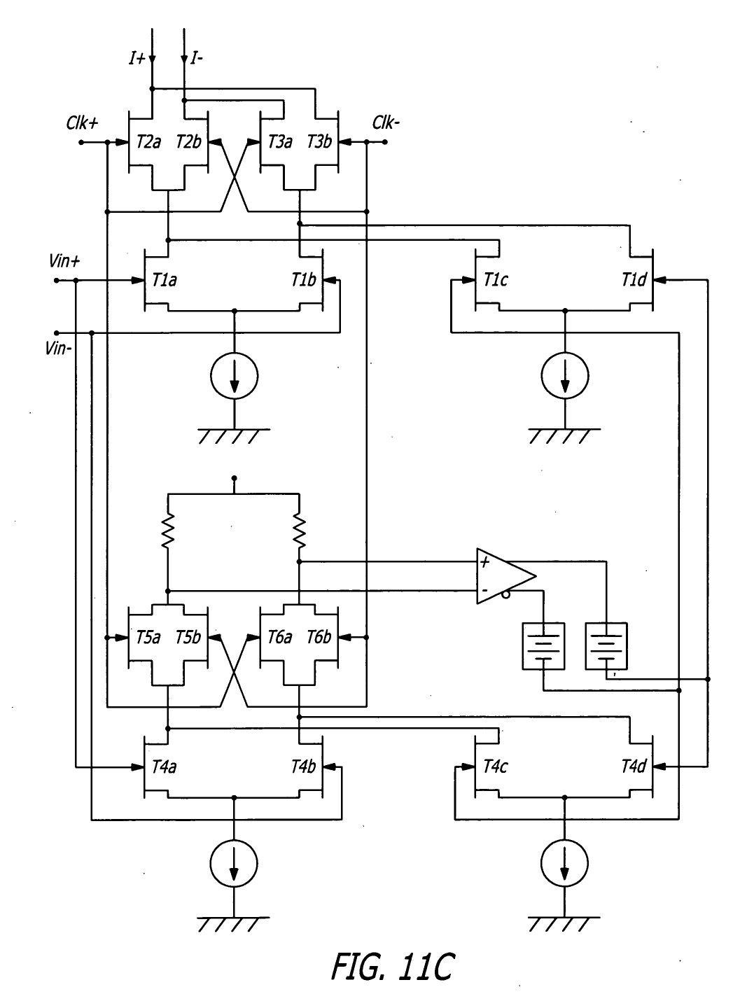

The invention may also be implemented using “fully differential” circuits. In this approach all signals are delivered as complementary pairs. The block diagram of such an implementation is shown in FIG. 11A. The complementary pairs (va+, va−) and (vb+, vb−) are effectively summed together to comprise the total current. Thus the effect of feeding the inverting output Vout− to vb+ and feeding the non-inverting output Vout+ to vb− is to negate the signal. Using this paradigm, therefore, the operation of negation is accomplished by reversing a pair of complementary signals.

The aforementioned approach has an advantage in that it has the ability to reject any common mode crosstalk noise since both “+” and “−” input terminals receive identical crosstalk signals. Furthermore, since the voltage-to-current converters can be arranged to operate at a fixed common mode voltage (i.e., 0.5·(Vₒᵤₜ⁺+Vₒᵤₜ⁻) is a constant voltage), the usual distorting effects of differential amplifiers are somewhat avoided.

Two common transistor-level implementations of the block diagram shown FIG. 10A using BJT and FET devices are shown in FIG. 10B and FIG. 10C, respectively. Note that a “dummy” switching network is provided (in the form of T5a, T5b, T6a, and T6b). Unlike the commutator network (T2a, T2b, T3a, and T3b) the “dummy” switching network does not invert the polarity of the current produced by the differential pair (T4a, T4b) on opposite half-cycles of the clock signal. That is, the dummy switching network has substantially no operational effect within the amplifier. The sole function of the dummy switching network is to replicate in the differential pair (T4a, T4b) the operating conditions imposed by the commutator network on the differential pair (T1a, T1b). The dummy switching network includes two transistor pairs, each transistor pair having commonly connected emitter notes (or sources notes for FETs) and commonly connected collector nodes (or drain notes for FETs), with one of the base nodes (or gates for FETs) being connected to a first clock and the other of the base nodes (or gate nodes for FETs) being connected to a second clock having the opposite polarity from the first clock. In contrast, the transistor pairs (T2a, T2b) and (T3a, T3b) within the amplification stage have commonly connected emitter (or source) nodes, and have a first clock connected to the first transistor's base (or gate) and a clock of opposite polarity connected to the second transistor's base (or gate), but do not have commonly connected collector (or drain) nodes. The pull-up device, shown here as resistor 1005, must have a highly linear voltage versus current characteristic. An optional amplifier 1006 is shown and can be used to boost the open-loop gain of the feedback amplifier, thereby improving the fidelity of the predistortion operation. A level-shift network shown as 1008 in the figure can also be used within the feedback loop to ensure that sufficient base-emitter voltage (or drain-source voltage for the FET implementation) is provided such that all devices operate in their active regions.

FIG. 11B is a bipolar junction transistor (BJT) implementation of the fully differential block diagram of FIG. 11A, and FIG. 11C is a field effect transistor (FET) implementation. Explanations in the preceding paragraphs regarding the “dummy” switching network (designated as T5a, T5b, T6a, and T6b) apply to these circuits as well. The primary physical difference between the common circuits shown in FIGS. 10B and 10C and the differential mode circuits shown in FIGS. 11B and 11C is that the differential mode circuits use a completely separate differential pair to apply the necessary negative feedback.

The fully differential approach typically requires external circuits to precisely set the values of the current sources in order to avoid having a common mode output voltage that is either too high, thus limiting the useful “headroom” of the circuit, or too low, causing the circuit to exhibit excessive distortion even to moderately small input signals. Designs for such circuits are commonly available in the literature and can be used in conjunction with this invention without changing its operation; therefore, specific references to such circuits have been omitted for the sake of brevity.

When used for radio frequency applications, the circuit disclosed herein will operate within the radio frequency range, typically greater than 1 MHz.

It will be appreciated that the term “present invention” as used herein should not be construed to mean that only a single invention having a single essential element or group of elements is presented. Similarly, it will also be appreciated that the term “present invention” encompasses a number of separate innovations which can each be considered separate inventions. Although the present invention has thus been described in detail with regard to the preferred embodiments and drawings thereof, it should be apparent to those skilled in the art that various adaptations and modifications of the present invention may be accomplished without departing from the spirit and the scope of the invention. For example, although the invention has been described with reference to a voltage follower, voltage-to-current-converters, and a current-to-voltage converter, it will be apparent that the invention could be implemented using other types of signal followers and other types of converters. It will also be apparent that the polarities of various signals illustrated herein can be reversed and still achieve the same basic operation and the same basic linearizing results. Accordingly, it is to be understood that the detailed description and the accompanying drawings as set forth hereinabove are not intended to limit the breadth of the present invention, which should be inferred only from the following claims and their appropriately construed legal equivalents.

We claim:

1. A circuit comprising:
a first stage comprising an input follower, the input follower having a differential input comprising a plus input and a minus input, and further having an output operationally connected to said minus input;
a second stage comprising an amplification stage having a differential input comprising a plus input and a minus input; wherein:
an input signal is operationally connected to both the input follower plus input and to a first one of the inputs to the amplification stage; and
the output of the input follower is further operationally connected to a second one of the inputs to the amplification stage.

2. The circuit of claim 1 wherein:
the input follower stage comprises a first transducer that changes a signal from a first form to a second form, and a second transducer that changes a signal from the second form to the first form; and
the amplification stage comprises a third transducer that changes a signal from the first form to the second form.

3. The circuit of claim 1 wherein:
the difference between the plus input and the minus input to the amplification stage corresponds to an inverse of a nonlinear characteristic of the amplification stage, thereby compensating for said nonlinear characteristic.

4. The circuit of claim 1 wherein said circuit is a commutating amplifier used to shift a signal directly between a baseband frequency and a radio frequency without first shifting the signal to an intermediate frequency.

5. A commutating circuit for commutating an input signal comprising:
a first voltage-to-current converter operationally connected to the input signal;
a second voltage-to-current converter, the second voltage-to-current converter having a first half of a differential input operationally connected to the input signal;
a current-to-voltage converter for converting an output from the first voltage-to-current converter to a feedback voltage signal, the feedback voltage signal being connected to a negative input to the first voltage-to-current converter and further operationally connected to a second half of the differential input to the second voltage-to-current converter; and
a current mode switch operationally connected to an output of the second voltage-to-current converter;
wherein the first voltage-to-current converter and the current-to-voltage converter together form a closed loop amplifier having an open loop gain of greater than 20 and a closed loop gain of approximately unity.

6. The circuit of claim 5 wherein the first and second voltage-to-current converters substantially comprise Gilbert multiplier cells, and the current-to-voltage converter comprises a resistor.

7. The circuit of claim 5 wherein said closed loop amplifier defines a first amplifier, said first amplifier including a second amplifier within a feedback loop of the first amplifier such that the open loop gain of the first amplifier is increased.

8. The circuit of claim 5 wherein said closed loop amplifier further comprises a level shift network within a feedback loop thereof and a feedback voltage associated therewith in order to shift the feedback voltage such that a transistor within the closed loop amplifier is operated within a nearly linear region.

9. The circuit of claim 5 wherein said circuit defines a commutator used to multiply a baseband signal by a radio frequency clock signal, thereby producing a version of the baseband signal upconverted to radio frequency for transmission over a wireless network.

10. The circuit of claim 5 wherein said circuit defines a commutator used to multiply a received radio frequency signal by a radio frequency clock signal, thereby producing a version of the received signal downconverted to baseband.

11. The circuit of claim 5 wherein said circuit is a fully differential circuit.

12. The circuit of claim 5 wherein said first voltage-to-current converter includes a first transistor pair comprising first and second transistors, the first transistor pair having commonly connected emitter or source nodes, and commonly connected collector or drain nodes, with a base or gate node of the first transistor being connected to a first clock, and a base or gate node of the second transistor being connected to a second clock having a polarity opposite to that of the first clock.

13. The circuit of claim 12 wherein said second voltage-to-current converter includes a second transistor pair comprising third and fourth transistors, the second transistor pair having commonly connected source or emitter nodes, and further having collector or drain nodes that are not commonly connected, and wherein the first clock is connected to a base or gate node of the third transistor and the second clock is connected to a base or gate node of the fourth transistor.

14. A method of linearizing an amplifier comprising:
providing a first amplification section on an integrated circuit, the first amplification section receiving an input signal and producing a first amplifier output in response thereto;
providing a second amplification section on the integrated circuit;
amplifying within the second amplification section a difference between the input signal and the first amplifier output;
wherein said difference has a nonlinearity produced by characteristics of the first amplification section that approximates the inverse of a nonlinearity of the second amplification section, thereby at least partially compensating for nonlinearity within said second amplification section and producing a more nearly linear overall transfer function than for said second amplification section alone.

15. The method of claim 14 further comprising:
closely matching architectures of said first and second amplification sections so that nonlinearities associated with said amplifications sections are closely matched, thereby improving linearity in the overall transfer function of said amplifier.

16. The method of claim 15 wherein:
said second amplification section controls a first current switch which is switched by a clock signal operating at greater than 1 MHz; and
said matching includes providing a second current switch which is switched by said clock signal, said second current switch having substantially no operational effect within said amplifier other than to provide loading characteristics which closely match loading characteristics produced by said first current switch.

17. The method of claim 14 wherein said first amplification section comprises a closed loop amplifier having a feedback loop, and the method further comprises providing a third amplification section and a level shifter within said feedback loop.

18. The method of claim 14 wherein said first amplification section comprises:
a voltage-to-current converter; and
a current-to-voltage converter comprising at least one resistor, a voltage output from said current-to-voltage converter configured to provide feedback to an input of the voltage-to-current converter such that the voltage-to-current-converter and the current-to-voltage converter together define a voltage follower.

19. The method of claim 18 wherein said amplification includes at least one amplifier operationally disposed after said resistor and before an input node to said voltage-to-current converter.

20. The method of claim 18 wherein the method further comprises providing amplification within said voltage follower such that said voltage follower has an open loop gain of greater than 100.
